(19) United States
(12) Patent Application Publication
(10) Pub. No.: US 2025/0150068 A1
(43) Pub. Date: May 8, 2025

(54) DYNAMIC LATCH, DYNAMIC D FLIP-FLOP, DATA OPERATION UNIT, CHIP, HASH BOARD, AND COMPUTING DEVICE

(71) Applicant: CANAAN CREATIVE (SH) CO., LTD., Shanghai (CN)

(72) Inventors: Shuangwen CHEN, Beijing (CN); Zhi LI, Shanghai (CN); Nangeng ZHANG, Beijing (CN)

(21) Appl. No.: 19/020,267

(22) Filed: Jan. 14, 2025

Related U.S. Application Data
(63) Continuation of application No. PCT/CN2023/093276, filed on May 10, 2023.

(30) Foreign Application Priority Data
Jul. 14, 2022 (CN) 202210855768.1

(51) Int. Cl. H03K 5/15; H03K 5/05

(52) U.S. Cl. CPC H03K 5/15066; H03K 5/05

(57) ABSTRACT

The invention provides a dynamic latch, comprising an input terminal for inputting a first data; an output terminal for outputting a second data; a clock signal terminal for supplying a clock signal; a data transmission unit for transmitting the first data under control of the clock signal; and a data output unit for converting the first data into the second data. The data transmission unit and the data output unit are sequentially connected in series between the input terminal and the output terminal, and a node is provided between the data transmission unit and the data output unit. The dynamic latch further comprises a data retention unit electrically connected to the node. The retention time of data can be effectively extended, thereby improving data security and accuracy.

### CROSS-REFERENCES TO RELATED APPLICATION

This application is a continuation of International Application No. PCT/CN2023/093276, filed on May 10, 2023, which claims priority to Chinese Patent Application No. 202210855768.1, filed with the China National Intellectual Property Administration on Jul. 14, 2022, both of which are hereby incorporated by reference in their entirety.

### TECHNICAL FIELD

The invention relates to a clock-controlled storage device, and particularly to a dynamic latch, a dynamic D flip-flop, a data operation unit, a chip, a hash board and a computing device applied to large-scale data operating equipment.

### BACKGROUND

Dynamic latches and dynamic flip-flops are widely applied, and may be used for registering of digital signals. In the existing dynamic latch and dynamic flip-flop, the transmitted data are often temporarily stored in a parasitic capacitance generated by transistors constituting a latch unit. However, since the operation frequency is gradually improved, the temporarily stored data easily generate dynamic leakage current, causing insufficient data retention time, and leading to data loss and reducing accuracy of operation.

Therefore, how to effectively improve data retention time in the dynamic latch or dynamic flip-flop is actually the problem to be solved.

### SUMMARY

To solve the above problem, the invention provides a dynamic latch and a dynamic D flip-flop capable of effectively increasing data retention time, and improving security and accuracy of data.

To achieve the object, the invention provides a dynamic latch, comprising: an input terminal for inputting a first data; an output terminal for outputting a second data; a clock signal terminal for supplying a clock signal; a data transmission unit for transmitting the first data under control of the clock signal; and a data output unit for converting the first data into the second data; the data transmission unit and the data output unit are sequentially connected in series between the input terminal and the output terminal, and a node is provided between the data transmission unit and the data output unit; wherein, further comprising a data retention unit electrically connected to the node.

In the dynamic latch, the data retention unit comprises a PMOS transistor and/or a NMOS transistor.

In the dynamic latch, the PMOS transistor has a source terminal, a drain terminal and a gate terminal, the source terminal and the drain terminal of the PMOS transistor are electrically connected to the node, and the gate terminal of the PMOS transistor is electrically connected to a power supply.

In the dynamic latch, the NMOS transistor has a source terminal, a drain terminal and a gate terminal, the source terminal and the drain terminal of the NMOS transistor are electrically connected to the node, and the gate terminal of the NMOS transistor is electrically connected to a ground.

In the dynamic latch, the PMOS transistor has a source terminal, a drain terminal and a gate terminal, the source terminal and the drain terminal of the PMOS transistor are electrically connected to a power supply, and the gate terminal of the PMOS transistor is electrically connected to the node.

In the dynamic latch, the NMOS transistor has a source terminal, a drain terminal and a gate terminal, the source terminal and the drain terminal of the NMOS transistor are electrically connected to a ground, and the gate terminal of the NMOS transistor is electrically connected to the node.

In the dynamic latch, the PMOS transistor has a source terminal, a drain terminal and a gate terminal, the source terminal and the gate terminal of the PMOS transistor are electrically connected to a power supply, and the drain terminal of the PMOS transistor is electrically connected to the node.

In the dynamic latch, the NMOS transistor has a source terminal, a drain terminal and a gate terminal, the source terminal and the gate terminal of the NMOS transistor are electrically connected to a ground, and the drain terminal of the NMOS transistor is electrically connected to the node.

In the dynamic latch, the clock signal comprises a first clock signal and a second clock signal in a opposite phase.

In the dynamic latch, the data transmission unit is a transmission gate.

In the dynamic latch, the transmission gate comprises a plurality of PMOS transistors and a plurality of NMOS transistors connected in parallel, respectively.

In the dynamic latch, the data output unit is an inverter.

In order to achieve the object, the invention provides a dynamic D flip-flop, comprising: an input terminal for inputting a first data; an output terminal for outputting a second data; a clock signal terminal for supplying a clock signal; a first latch latching the first data under control of the clock signal; a second latch receiving and latching data transmitted by the first latch; the first latch and the second latch are sequentially connected in series between the input terminal and the output terminal, the first latch comprises a first data transmission unit and a first data output unit, the second latch comprises a second data transmission unit and a second data output unit, a first node is provided between the first data transmission unit and the first data output unit, and a second node is provided between the second data transmission unit and the second data output unit; wherein, further comprising a data retention unit electrically connected to the first node and/or the second node.

In the dynamic D flip-flop, the data retention unit has a first terminal electrically connected to the first node, and a second terminal electrically connected to the second node.

In the dynamic D flip-flop, the data retention unit comprises a PMOS transistor and/or a NMOS transistor.

In the dynamic D flip-flop, the PMOS transistor has a source terminal electrically connected to the first node or the second node, a drain terminal electrically connected to the second node or the first node, and a gate terminal electrically connected to a power supply.

In the dynamic D flip-flop, the NMOS transistor has a source terminal electrically connected to the first node or the second node, a drain terminal electrically connected to the second node or the first node, and a gate terminal electrically connected to a ground.

In the dynamic D flip-flop, the PMOS transistor has a source terminal, a drain terminal and a gate terminal, the source terminal and the drain terminal of the PMOS transistor are electrically connected to the first node or the second node, and the gate terminal of the PMOS transistor is electrically connected to the second node or the first node.

In the dynamic D flip-flop, the NMOS transistor has a source terminal, a drain terminal and a gate terminal, the source terminal and the drain terminal of the NMOS transistor are electrically connected to the first node or the second node, and the gate terminal of the NMOS transistor is electrically connected to the second node or the first node.

In the dynamic D flip-flop, the data retention unit is electrically connected to the first node or the second node, and the data retention unit comprises a PMOS transistor and/or a NMOS transistor.

In the dynamic D flip-flop, the PMOS transistor has a source terminal, a drain terminal and a gate terminal, the source terminal and the drain terminal of the PMOS transistor are electrically connected to the first node, and the gate terminal of the PMOS transistor is electrically connected to a power supply.

In the dynamic D flip-flop, the NMOS transistor has a source terminal, a drain terminal and a gate terminal, the source terminal and the drain terminal of the NMOS transistor are electrically connected to the first node, and the gate terminal of the NMOS transistor is electrically connected to a ground.

In the dynamic D flip-flop, the PMOS transistor has a source terminal, a drain terminal and a gate terminal, the source terminal and the drain terminal of the PMOS transistor are electrically connected to a power supply, and the gate terminal of the PMOS transistor is electrically connected to the first node.

In the dynamic D flip-flop, the NMOS transistor has a source terminal, a drain terminal and a gate terminal, the source terminal and the drain terminal of the NMOS transistor are electrically connected to a ground, and the gate terminal of the NMOS transistor is electrically connected to the first node.

In the dynamic D flip-flop, the PMOS transistor has a source terminal, a drain terminal and a gate terminal, the source terminal and the gate terminal of the PMOS transistor are electrically connected to a power supply, and the drain terminal of the PMOS transistor is electrically connected to the first node.

In the dynamic D flip-flop, the NMOS transistor has a source terminal, a drain terminal and a gate terminal, the source terminal and the gate terminal of the NMOS transistor are electrically connected to a ground, and the drain terminal of the NMOS transistor is electrically connected to the first node.

In the dynamic D flip-flop, the PMOS transistor has a source terminal, a drain terminal and a gate terminal, the source terminal and the drain terminal of the PMOS transistor are electrically connected to the second node, and the gate terminal of the PMOS transistor is electrically connected to a power supply.

In the dynamic D flip-flop, the NMOS transistor has a source terminal, a drain terminal and a gate terminal, the source terminal and the drain terminal of the NMOS transistor are electrically connected to the second node, and the gate terminal of the NMOS transistor is electrically connected to a ground.

In the dynamic D flip-flop, the PMOS transistor has a source terminal, a drain terminal and a gate terminal, the source terminal and the drain terminal of the PMOS transistor are electrically connected to a power supply, and the gate terminal of the PMOS transistor is electrically connected to the second node.

In the dynamic D flip-flop, the NMOS transistor has a source terminal, a drain terminal and a gate terminal, the source terminal and the drain terminal of the NMOS transistor are electrically connected to a ground, and the gate terminal of the NMOS transistor is electrically connected to the second node.

In the dynamic D flip-flop, the PMOS transistor has a source terminal, a drain terminal and a gate terminal, the source terminal and the gate terminal of the PMOS transistor are electrically connected to a power supply, and the drain terminal of the PMOS transistor is electrically connected to the second node.

In the dynamic D flip-flop, the NMOS transistor has a source terminal, a drain terminal and a gate terminal, the source terminal and the gate terminal of the NMOS transistor are electrically connected to a ground, and the drain terminal of the NMOS transistor is electrically connected to the second node.

In the dynamic D flip-flop, the clock signal comprises a first clock signal and a second clock signal in a opposite phase.

In the dynamic D flip-flop, the data transmission unit is a transmission gate.

In the dynamic D flip-flop, the data output unit is an inverter.

To better achieve the object, the invention further provides a data operation unit, comprising a control circuit, an operational circuit and a plurality of dynamic latches interconnected with each other, the plurality of dynamic latches are connected in series and/or in parallel; wherein the plurality of dynamic latches are any of the dynamic latch.

To better achieve the object, the invention further provides a data operation unit, comprising a control circuit, an operational circuit and a plurality of dynamic D flip-flops interconnected with each other, the plurality of dynamic D flip-flops are connected in series and/or in parallel; wherein the plurality of dynamic D flip-flops are any of the dynamic D flip-flop.

To better achieve the object, the invention further provides a chip, comprising at least any one of the data operation unit.

To better achieve the object, the invention further provides a hash board for a computing device, comprising at least any one of the chip.

To better achieve the object, the invention further provides a computing device, comprising a power supply board, a control board, a connection board, a radiator and a plurality of hash boards, the control board is connected to the hash boards through the connection board, the radiator is disposed around the hash boards, the power supply board is configured to supply a power supply to the connection board, the control board, the radiator and the hash boards, wherein the hash boards are any of the hash board.

Hereinafter, the invention will be described in detail with reference to the accompanying drawings and the detailed embodiments, but the invention is not limited thereto.

### BRIEF DESCRIPTION OF THE DRAWINGS

FIG. 1 is a schematic diagram of a circuit of a dynamic latch in one embodiment of the invention.

FIG. 2 is a schematic diagram of a circuit of a dynamic latch in another embodiment of the invention.

FIG. 3 is a schematic diagram of a circuit of a dynamic latch in still another embodiment of the invention.

FIG. 4 is a schematic diagram of a circuit of a dynamic D flip-flop in one embodiment of the invention.

FIG. 5 is a schematic diagram of a circuit of a dynamic D flip-flop in another embodiment of the invention.

FIG. 6 is a schematic diagram of a circuit of a dynamic D flip-flop in another embodiment of the invention.

FIG. 7 is a schematic diagram of a circuit of a dynamic D flip-flop in still another embodiment of the invention.

FIG. 8 is a schematic diagram of a circuit of a dynamic D flip-flop in an extended embodiment of the invention.

FIG. 9 is a schematic diagram of a data operation unit of the invention.

FIG. 10 is a schematic diagram of a chip of the invention.

FIG. 11 is a schematic diagram of a hash board of the invention.

FIG. 12 is a schematic diagram of a computing device of the invention.

In the figures, reference signs are as follows:
100: dynamic latch
101: data transmission unit
102: data output unit
103: data retention unit
   103P: PMOS transistor
   103N: NMOS transistor
200: dynamic D flip-flop
201: first latch
202: second latch
203: data retention unit
   203P: PMOS transistor
   203N: NMOS transistor
800: data operation unit
801: control circuit
802: operational circuit
900: chip
901: control unit
1000: hash board
1100: computing device
1101: connection board
1102: control board
1103: radiator
1104: power supply board
D: input terminal
Q: output terminal
CLK1: first clock signal terminal
CLK2: second clock signal terminal
CKP, CKN: clock signal
S0: first node
S1: second node.

### DETAILED DESCRIPTION

Hereinafter structure principle and working principle of the invention are described in detail with reference to the accompanying drawings:

Specific terms are used in the specification and subsequent claims to refer to specific components. Those skilled in the art shall understand that the manufacturers may use different terms to name the same component. The specification and subsequent claims distinguish components from each other by different functions of the components, instead of different names.

“Comprise” and “include” mentioned in the whole specification and subsequent claims are open words, and shall be interpreted as “include but not limited to”. Moreover, the word “connection” herein includes any direct and indirect electrical connection means. The indirect electrical connection means comprises connecting through other devices.

### Embodiment One

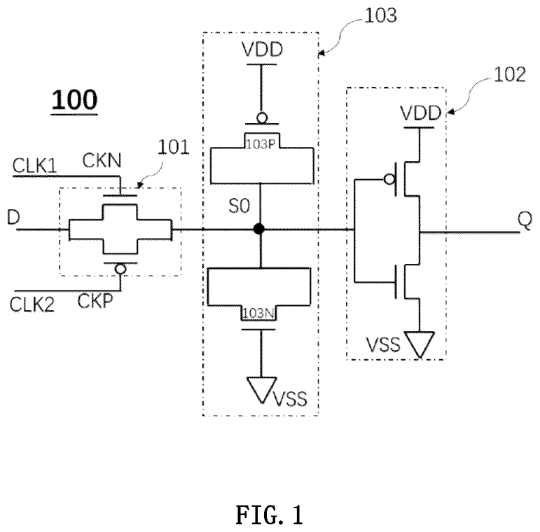

FIG. 1 is a schematic diagram of a circuit of a dynamic latch in one embodiment of the invention. As shown in FIG. 1, the dynamic latch 100 of the invention comprises an input terminal D, an output terminal Q, a first clock signal terminal CLK1, a second clock signal terminal CLK2, a data transmission unit 101 and a data output unit 102. The data transmission unit 101 and the data output unit 102 are sequentially connected in series between the input terminal D and the output terminal Q, and a first node S0 is formed between the data transmission unit 101 and the data output unit 102. In the dynamic latch 100, the input terminal D is configured for inputting data that need to be transmitted from the outside to the dynamic latch 100, the output terminal Q is configured for outputting the data that need to be transmitted from the dynamic latch 100 to the outside, and the first clock signal terminal CLK1 and the second clock signal terminal CLK2 are configured for supplying a clock control signal to the dynamic latch 100, and the clock control signal comprises a clock signal CKN and a clock signal CKP configured to control on and off of the data transmission unit 101. The clock signal CKN and the clock signal CKP are inverted clock signals, and data outputted from the output terminal and data inputted from the input terminal are inverted data signals.

Specifically, as shown in FIG. 1, the data transmission unit 101 of the dynamic latch 100 is a transmission gate structure, and the data transmission unit 101 comprises a PMOS transistor and a NMOS transistor connected in parallel. One terminal of the data transmission unit 101 is electrically connected to the input terminal D, and the other terminal of the data transmission unit 101 is electrically connected to the first node S0. In the data transmission unit 101, a gate terminal of the NMOS transistor is electrically connected to the clock signal CKN, and a gate terminal of the PMOS transistor is electrically connected to the clock signal CKP. When CKP is at a low level, CKN is at a high level, the PMOS transistor and the NMOS transistor of the data transmission unit 101 are both in a turn-on state, and the input terminal D transmits the data that need to be transmitted to the first node S0 through the data transmission unit 101. When CKP is at a high level, CKN is at a low level, the PMOS transistor and the NMOS transistor of the data transmission unit 101 are both in a turn-off state, the data at the input terminal D cannot be transmitted to the first node S0 through the data transmission unit 101, and the data transmission unit 101 latches the data transmitted to the first node S0 in the previous time period. In this embodiment, the data transmission unit 101 takes the transmission gate structure as an example. Of course, the data transmission unit 101 can also be other forms of analog switch units such as a three-state inverter, only if the switch function can be achieved under control of the clock signal, but the invention is not limited thereto.

To improve the transmission speed, the data transmission unit 101 in the invention may further comprise a plurality of PMOS transistors and a plurality of NMOS transistors connected in parallel, respectively.

As shown in FIG. 1, the data output unit 102 of the dynamic latch 100 in the invention is an inverter structure, which inverts and registers data received from the data transmission unit 101 to form data in opposite phase from the data at the input terminal D, and outputs data through the output terminal Q. Meanwhile, the data output unit 102 also can improve driving capability of the data.

The dynamic latch 100 further comprises a data retention unit 103. In this embodiment, the data retention unit 103 comprises a PMOS transistor 103P and a NMOS transistor 103N electrically connected to the first node S0, respectively. Specifically, a source terminal and a drain terminal of the PMOS transistor 103P are connected in parallel and electrically connected to the first node S0, and a gate terminal of the PMOS transistor 103P is electrically connected to a power supply VDD. A source terminal and a drain terminal of the NMOS transistor 103N are connected in parallel and electrically connected to the first node S0, and a gate terminal of the NMOS transistor 103N is electrically connected to a ground VSS.

Since the gate terminal of the PMOS transistor 103P in the data retention unit 103 is electrically connected to the power supply VDD, and the gate terminal of the NMOS transistor 103N is electrically connected to the ground VSS, under driving of a high-level signal of the power supply VDD, the PMOS transistor 103P is in a turn-off state, and under driving of a low level signal of the ground VSS, the NMOS transistor 103N is also in a turn-off state. At this time, the data retention unit 103 is equivalent to a capacitor for assisting in storing data latched at the first node S0, extending the retention time of data, improving stability of data storage, and thereby enhancing data security and accuracy.

It shall be noted that in the invention, the PMOS transistor 103P and the NMOS transistor 103N in the data retention unit 103 may together serve as the data retention unit 103, and also may separately serve as the data retention unit 103. In other words, the data retention unit 103 may comprise the PMOS transistor 103P and the NMOS transistor 103N, and also may comprise the PMOS transistor 103P or the NMOS transistor 103N only, but the invention is not limited thereto.

As an example:

The PMOS transistor 103P has a source terminal, a drain terminal and a gate terminal, the source terminal and the drain terminal of the PMOS transistor 103P are electrically connected to the node, and the gate terminal of the PMOS transistor 103P is electrically connected to a power supply.

The NMOS transistor 103N has a source terminal, a drain terminal and a gate terminal, the source terminal and the drain terminal of the NMOS transistor 103N are electrically connected to the node, and the gate terminal of the NMOS transistor 103N is electrically connected to a ground.

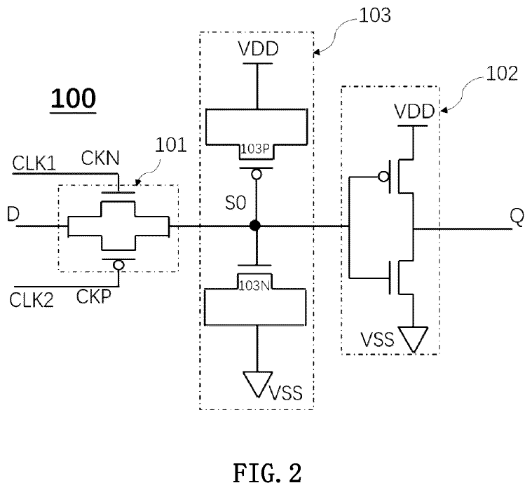

FIG. 2 is a schematic diagram of a circuit of a dynamic latch in another embodiment of the invention. Difference from the embodiment shown in FIG. 1 is that the specific connection method of the PMOS transistor 103P and the NMOS transistor 103N in the data retention unit 103 is different. As shown in FIG. 2, in this embodiment, a source terminal and a drain terminal of the PMOS transistor 103P are connected in parallel and electrically connected to the power supply VDD, and a gate terminal of the PMOS transistor 103P is electrically connected to the first node S0. A source terminal and a drain terminal of the NMOS transistor 103N are connected in parallel and electrically connected to the ground VSS, and a gate terminal of the NMOS transistor 103N is electrically connected to the first node S0.

Similarly, the PMOS transistor 103P and the NMOS transistor 103N in the data retention unit 103 serve as a capacitor for assisting in storing data latched at the first node S0, extending the retention time of data, improving stability of data storage, and thereby enhancing data security and accuracy.

It shall be noted that in the invention, the PMOS transistor 103P and the NMOS transistor 103N in the data retention unit 103 may together serve as the data retention unit 103, and also may separately serve as the data retention unit 103. In other words, the data retention unit 103 may comprise the PMOS transistor 103P and the NMOS transistor 103N, and also may comprise the PMOS transistor 103P or the NMOS transistor 103N only, but the invention is not limited thereto.

As an example:

The PMOS transistor 103P has a source terminal, a drain terminal and a gate terminal, the source terminal and the drain terminal of the PMOS transistor 103P are electrically connected to a power supply, and the gate terminal of the PMOS transistor 103P is electrically connected to the node.

The NMOS transistor 103N has a source terminal, a drain terminal and a gate terminal, the source terminal and the drain terminal of the NMOS transistor 103N are electrically connected to a ground, and the gate terminal of the NMOS transistor 103N is electrically connected to the node.

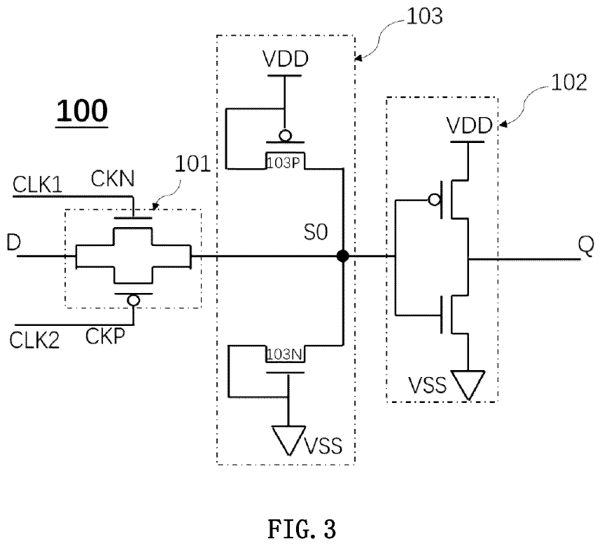

FIG. 3 is a schematic diagram of a circuit of a dynamic latch in still another embodiment of the invention. Difference from the embodiments shown in FIGS. 1 and 2 is that the connection method of the PMOS transistor 103P and the NMOS transistor 103N in the data retention unit 103 is different. As shown in FIG. 3, in this embodiment, a source terminal and a gate terminal of the PMOS transistor 103P are connected in parallel and electrically connected to the power supply VDD, and a drain terminal of the PMOS transistor 103P is electrically connected to the first node S0. A source terminal and a gate terminal of the NMOS transistor 103N are connected in parallel and electrically connected to the ground VSS, and a drain terminal of the NMOS transistor 103N is electrically connected to the first node S0.

Similarly, the PMOS transistor 103P and the NMOS transistor 103N in the data retention unit 103 serve as a capacitor for assisting in storing data latched at the first node S0, extending the retention time of data, improving stability of data storage, and thereby enhancing data security and accuracy.

It shall be noted that in the invention, the PMOS transistor 103P and the NMOS transistor 103N in the data retention unit 103 may together serve as the data retention unit 103, and also may separately serve as the data retention unit 103. In other words, the data retention unit 103 may comprise the PMOS transistor 103P and the NMOS transistor 103N, and also may comprise the PMOS transistor 103P or the NMOS transistor 103N only, but the invention is not limited thereto.

As an example:

The PMOS transistor 103P has a source terminal, a drain terminal and a gate terminal, the source terminal (or the drain terminal) and the gate terminal of the PMOS transistor 103P are electrically connected to a power supply, and the drain terminal (or the source terminal) of the PMOS transistor 103P is electrically connected to the node.

The NMOS transistor 103N has a source terminal, a drain terminal and a gate terminal, the source terminal (or the drain terminal) and the gate terminal of the NMOS transistor 103N are electrically connected to a ground, and the drain terminal (or the source terminal) of the NMOS transistor 103N is electrically connected to the node.

The above embodiments are illustrated using one connection method of the PMOS transistor and the NMOS transistor, and the source electrode and the drain electrode in the PMOS transistor and the NMOS transistor may be interchanged, but the invention is not limited thereto.

### Embodiment Two

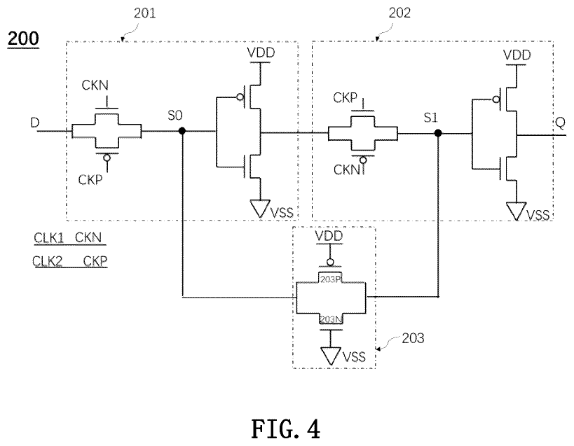

FIG. 4 is a schematic diagram of a circuit of a dynamic D flip-flop in one embodiment of the invention. As shown in FIG. 4, the dynamic D flip-flop 200 in the invention comprises an input terminal D, an output terminal Q, a first clock signal terminal CLK1, a second clock signal terminal CLK2, a first latch 201 and a second latch 202. The first latch 201 and the second latch 202 are sequentially connected in series between the input terminal D and the output terminal Q. Each of the first latch 201 and the second latch 202 in this embodiment adopts the structure of the dynamic latch in embodiment one, but the first latch 201 and the second latch 202 in this embodiment do not comprise a data retention unit, and are a basic dynamic latch structure.

A first node S0 is formed between the data transmission unit and the data output unit of the first latch 201, and a second node S1 is formed between the data transmission unit and the data output unit of the second latch 202. In the dynamic D flip-flop 200, the input terminal D is configured for inputting data that need to be transmitted from outside to the dynamic D flip-flop 200, the output terminal Q is configured for outputting the data that need to be transmitted from the dynamic D flip-flop 200 to outside, and the first clock signal terminal CLK1 and the second clock signal terminal CLK2 are configured for supplying a clock control signal to the dynamic D flip-flop 200, and the clock control signal comprises a clock signal CKN and a clock signal CKP configured to control on and off of the first latch 201 and the second latch 202. The clock signal CKN and the clock signal CKP are inverted clock signals, and the first latch 201 and the second latch 202 will not turn on or turn off at the same time.

The dynamic D flip-flop 200 further comprises a data retention unit 203. In this embodiment, the data retention unit 203 comprises a PMOS transistor 203P and a NMOS transistor 203N connected in parallel and electrically connected between the first node S0 and the second node S1. Specifically, a source terminal of the PMOS transistor 203P and a drain terminal of the NMOS transistor 203N are connected in parallel and electrically connected to the second node S1, a drain terminal of the PMOS transistor 203P and a source terminal of the NMOS transistor 203N are connected in parallel and electrically connected to the first node S0, a gate terminal of the PMOS transistor 203P is electrically connected to a power supply VDD, and a gate terminal of the NMOS transistor 203N is electrically connected to a ground VSS.

Since the gate terminal of the PMOS transistor 203P in the data retention unit 203 is electrically connected to the power supply VDD, and the gate terminal of the NMOS transistor 203N is electrically connected to the ground VSS, under driving of a high level signal of the power supply VDD, the PMOS transistor 203P is in a turn-off state, and under driving of a low level signal of the ground VSS, the NMOS transistor 203N is also in a turn-off state. At this time, the data retention unit 203 is equivalent to a capacitor for assisting in storing data latched at the first node S0 and data transmitted to the second node S1, extending the retention time of data, improving stability of data storage, and thereby enhancing data security and accuracy.

It shall be noted that in the invention, the PMOS transistor 203P and the NMOS transistor 203N in the data retention unit 203 may together serve as the data retention unit 203, and also may separately serve as the data retention unit 203. In other words, the data retention unit 203 may comprise the PMOS transistor 203P and the NMOS transistor 203N, and also may comprise the PMOS transistor 203P or the NMOS transistor 203N only, but the invention is not limited thereto.

As an example:

The PMOS transistor 203P has a source terminal electrically connected to the first node or the second node, a drain terminal electrically connected to the second node or the first node, and a gate terminal electrically connected to a power supply.

The NMOS transistor 203N has a source terminal electrically connected to the first node or the second node, a drain terminal electrically connected to the second node or the first node, and a gate terminal electrically connected to a ground.

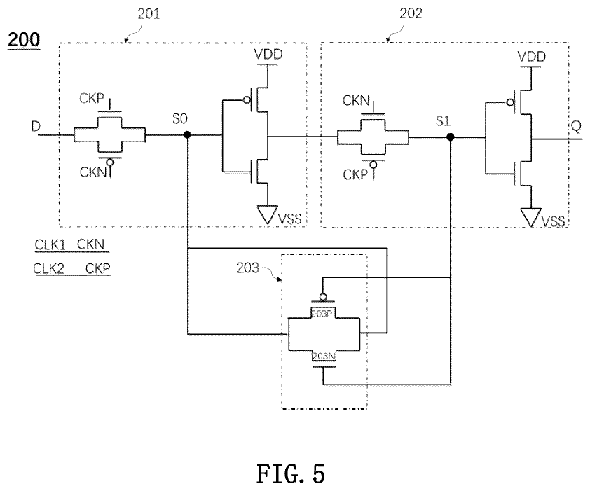

FIG. 5 is a schematic diagram of a circuit of a dynamic D flip-flop in another embodiment of the invention. The dynamic D flip-flop 200 shown in FIG. 5 differs from the embodiment shown in FIG. 4 in the structure of the data retention unit 203. As shown in FIG. 5, in this embodiment, the data retention unit 203 comprises a PMOS transistor 203P and a NMOS transistor 203N connected in parallel, a source terminal of the PMOS transistor 203P is electrically connected to a source terminal of the NMOS transistor 203N and electrically connected to the first node S0, a drain terminal of the PMOS transistor 203P is electrically connected to a drain terminal of the NMOS transistor 203N and electrically connected to the first node S0, and a gate terminal of the PMOS transistor 203P and a gate terminal of the NMOS transistor 203N are connected together and electrically connected to the second node S1.

Similarly, the PMOS transistor 203P and the NMOS transistor 203N in the data retention unit 203 serve as a capacitor for assisting in storing data latched at the first node S0 and data transmitted to the second node S1, extending the retention time of data, improving stability of data storage, and thereby enhancing data security and accuracy.

It shall be noted that in the invention, the PMOS transistor 203P and the NMOS transistor 203N in the data retention unit 203 may together serve as the data retention unit 203, and also may separately serve as the data retention unit 203. In other words, the data retention unit 203 may comprise the PMOS transistor 203P and the NMOS transistor 203N, and also may comprise the PMOS transistor 203P or the NMOS transistor 203N only, but the invention is not limited thereto.

As an example:

The PMOS transistor 203P has a source terminal, a drain terminal and a gate terminal, the source terminal and the drain terminal of the PMOS transistor 203P are electrically connected to the first node or the second node, and the gate terminal of the PMOS transistor 203P is electrically connected to the second node or the first node.

The NMOS transistor 203N has a source terminal, a drain terminal and a gate terminal, the source terminal and the drain terminal of the NMOS transistor 203N are electrically connected to the first node or the second node, and the gate terminal of the NMOS transistor 203N is electrically connected to the second node or the first node.

### Variable Embodiment

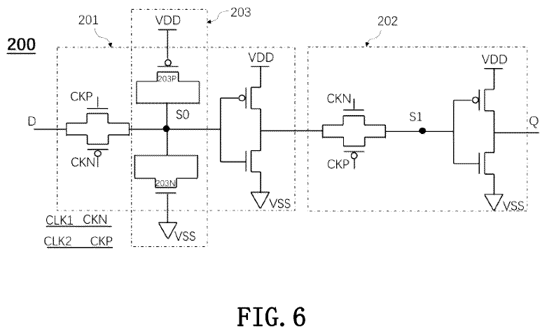

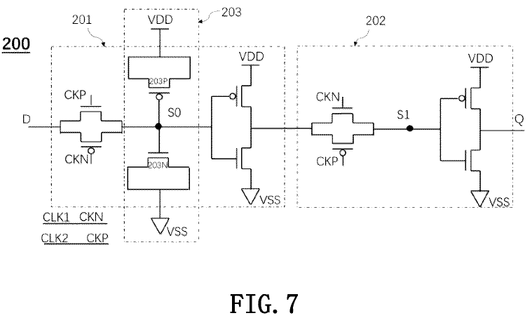

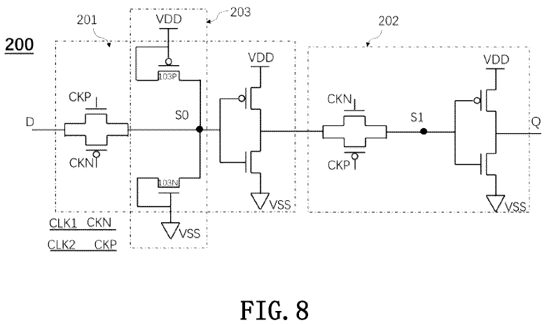

FIG. 6 is a schematic diagram of a circuit of a dynamic D flip-flop in another embodiment of the invention, FIG. 7 is a schematic diagram of a circuit of a dynamic D flip-flop in still another embodiment of the invention, and FIG. 8 is a schematic diagram of a circuit of a dynamic D flip-flop in an extended embodiment of the invention. Difference from the embodiments shown in FIGS. 4 and 5 is that in this embodiment, the data retention unit 203 is only electrically connected to the first node S0.

In other words, in the embodiment shown in FIG. 6, the first latch 201 has the same structure as the dynamic latch 100 in the embodiment shown in FIG. 1, in the embodiment shown in FIG. 7, the first latch 201 has the same structure as the dynamic latch 100 in the embodiment shown in FIG. 2, and in the embodiment shown in FIG. 8, the first latch 201 has the same structure as the dynamic latch 100 in the embodiment shown in FIG. 3. In the embodiments shown in FIGS. 6-8, the second latch 202 has the same structure as the first latch 201 or the second latch 202 shown in FIGS. 4-5, and in the embodiments shown in FIGS. 6-8, the first latch 201 and the second latch 202 are connected in series between the input terminal D and the output terminal Q.

Similarly, the PMOS transistor 203P and the NMOS transistor 203N in the data retention unit 203 serve as a capacitor for assisting in storing data latched at the first node S0, extending the retention time of data, improving stability of data storage, and thereby enhancing data security and accuracy.

It shall be noted that in the invention, the PMOS transistor 203P and the NMOS transistor 203N in the data retention unit 203 may together serve as the data retention unit 203, and also may separately serve as the data retention unit 203. In other words, the data retention unit 203 may comprise the PMOS transistor 203P and the NMOS transistor 203N, and also may comprise the PMOS transistor 203P or the NMOS transistor 203N only, but the invention is not limited thereto.

Of course, the data retention unit 203 may be disposed at the first node S0, and also may be disposed at the second node S1. Alternatively, the data retention units 203 are disposed at both the first node S0 and the second node S1, but the invention is not limited thereto.

As an example:

The PMOS transistor 203P has a source terminal, a drain terminal and a gate terminal, the source terminal and the drain terminal of the PMOS transistor 203P are electrically connected to the first node, and the gate terminal of the PMOS transistor 203P is electrically connected to a power supply.

The NMOS transistor 203N has a source terminal, a drain terminal and a gate terminal, the source terminal and the drain terminal of the NMOS transistor 203N are electrically connected to the first node, and the gate terminal of the NMOS transistor 203N is electrically connected to a ground.

The PMOS transistor 203P has a source terminal, a drain terminal and a gate terminal, the source terminal and the drain terminal of the PMOS transistor 203P are electrically connected to the second node, and the gate terminal of the PMOS transistor 203P is electrically connected to a power supply.

The NMOS transistor 203N has a source terminal, a drain terminal and a gate terminal, the source terminal and the drain terminal of the NMOS transistor 203N are electrically connected to the second node, and the gate terminal of the NMOS transistor 203N is electrically connected to a ground.

The PMOS transistor 203P has a source terminal, a drain terminal and a gate terminal, the source terminal and the drain terminal of the PMOS transistor 203P are electrically connected to a power supply, and the gate terminal of the PMOS transistor 203P is electrically connected to the first node.

The NMOS transistor 203N has a source terminal, a drain terminal and a gate terminal, the source terminal and the drain terminal of the NMOS transistor 203N are electrically connected to a ground, and the gate terminal of the NMOS transistor 203N is electrically connected to the first node.

The PMOS transistor 203P has a source terminal, a drain terminal and a gate terminal, the source terminal and the drain terminal of the PMOS transistor 203P are electrically connected to a power supply, and the gate terminal of the PMOS transistor 203P is electrically connected to the second node.

The NMOS transistor 203N has a source terminal, a drain terminal and a gate terminal, the source terminal and the drain terminal of the NMOS transistor 203N are electrically connected to a ground, and the gate terminal of the NMOS transistor 203N is electrically connected to the second node.

The PMOS transistor 203P has a source terminal, a drain terminal and a gate terminal, the source terminal (or the drain terminal) and the gate terminal of the PMOS transistor 203P are electrically connected to a power supply, and the drain terminal (or the source terminal) of the PMOS transistor 203P is electrically connected to the first node.

The NMOS transistor 203N has a source terminal, a drain terminal and a gate terminal, the source terminal (or the drain terminal) and the gate terminal of the NMOS transistor 203N are electrically connected to a ground, and the drain terminal (or the source terminal) of the NMOS transistor 203N is electrically connected to the first node.

The PMOS transistor 203P has a source terminal, a drain terminal and a gate terminal, the source terminal (or the drain terminal) and the gate terminal of the PMOS transistor 203P are electrically connected to a power supply, and the drain terminal (or the source terminal) of the PMOS transistor 203P is electrically connected to the second node.

The NMOS transistor 203N has a source terminal, a drain terminal and a gate terminal, the source terminal (or the drain terminal) and the gate terminal of the NMOS transistor 203N are electrically connected to a ground, and the drain terminal (or the source terminal) of the NMOS transistor 203N is electrically connected to the second node.

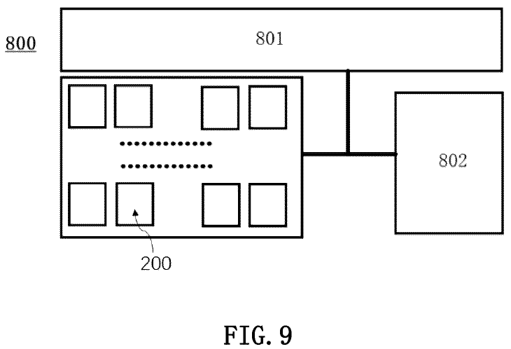

The invention further provides a data operation unit, and FIG. 9 is a schematic diagram of a data operation unit of the invention. As shown in FIG. 9, the data operation unit 800 comprises a control circuit 801, an operational circuit 802 and a plurality of dynamic D flip-flops 200, and the plurality of dynamic D flip-flops 200 are connected in series or in parallel. The control circuit 801 refreshes data in the dynamic D flip-flops 200 and reads data from the dynamic D flip-flops 200, the operational circuit 802 performs operation on the read data, and then an operation result is outputted by the control circuit 801.

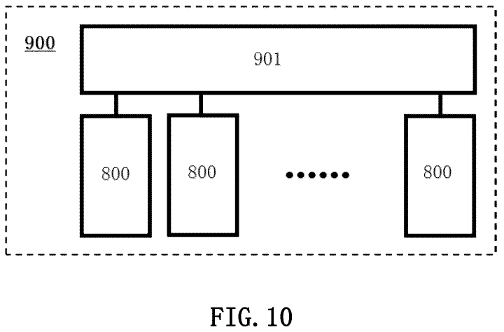

The invention further provides a chip, and FIG. 10 is a schematic diagram of a chip of the invention. As shown in FIG. 10, the chip 900 comprises a control unit 901 and one or more data operation units 800. The control unit 901 inputs data to the data operation units 800 and processes the data outputted from the data operation units 800.

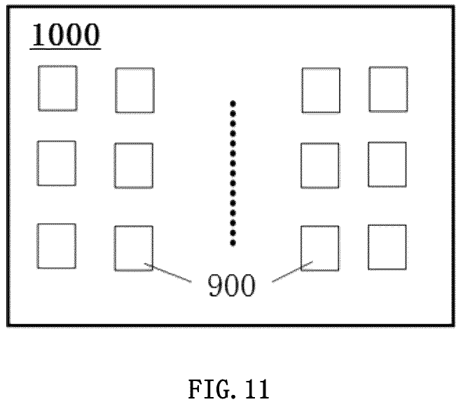

The invention further provides a hash board, and FIG. 11 is a schematic diagram of a hash board of the invention. As shown in FIG. 11, each hash board 1000 comprises one or more chips 900, which perform large-scale operations on working data sent downstream from the computing device.

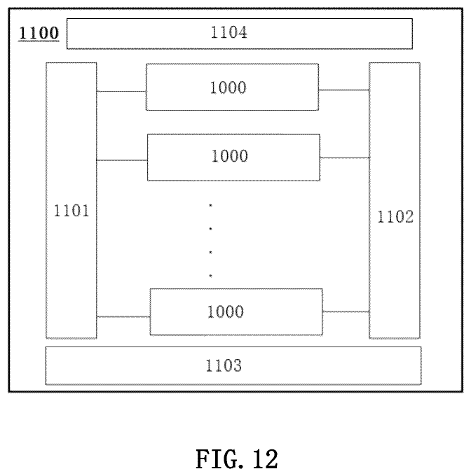

The invention further provides a computing device, which is preferably configured to operation of mining virtual digital currency, and of course, the computing device also may be configured to any other massive operations. FIG. 12 is a schematic diagram of a computing device of the invention. As shown in FIG. 12, each computing device 1100 comprises a connection board 1101, a control board 1102, a radiator 1103, a power supply board 1104 and one or more hash boards 1000. The control board 1102 is connected to the hash boards 1000 through the connection board 1101, and the radiator 1103 is disposed around the hash boards 1000. The power supply board 1104 is configured to supply a power supply to the connection board 1101, the control board 1102, the radiator 1103 and the hash boards 1000.

It shall be noted that in the description of the invention, the orientation or positional relationship indicated by terms “transverse”, “longitudinal”, “up”, “down”, “front”, “back”, “left”, “right”, “vertical”, “horizontal”, “top”, “bottom”, “in”, “out”, and the like is an orientation or positional relationship illustrated by the drawings, and is only for the purpose of describing the invention and simplifying the explanation, rather than indicating or suggesting that the referred device or element must have the specific orientation, or be constructed and operated in the specific orientation, so it shall not be understood as limit to the invention.

In other words, the invention may further have various other embodiments, and those skilled in the art shall make various corresponding modifications and variations according to the invention without departing from concept and essence of the invention, but these corresponding modifications and variations shall belong to the scope protected by the appended claims of the invention.

### INDUSTRIAL APPLICABILITY

Application of the dynamic latch in the invention has the following advantageous effects:

In the dynamic latch provided by the invention, the data retention unit is electrically connected to the storage node, which effectively extends the retention time of data, and improves data security and accuracy.

What is claimed is:

1. A dynamic latch, comprising:
an input terminal for inputting a first data;
an output terminal for outputting a second data;
a clock signal terminal for supplying a clock signal;
a data transmission unit for transmitting the first data under control of the clock signal; and
a data output unit for converting the first data into the second data,
wherein the data transmission unit and the data output unit are sequentially connected in series between the input terminal and the output terminal, and a node is provided between the data transmission unit and the data output unit, and
wherein the dynamic latch further comprises:
a data retention unit electrically connected to the node.

2. The dynamic latch according to claim 1, wherein the data retention unit comprises a PMOS transistor and/or a NMOS transistor.

3. The dynamic latch according to claim 2, wherein the PMOS transistor has a source terminal, a drain terminal and a gate terminal, the source terminal and the drain terminal of the PMOS transistor are electrically connected to the node, and the gate terminal of the PMOS transistor is electrically connected to a power supply.

4. The dynamic latch according to claim 2, wherein the NMOS transistor has a source terminal, a drain terminal and a gate terminal, the source terminal and the drain terminal of the NMOS transistor are electrically connected to the node, and the gate terminal of the NMOS transistor is electrically connected to a ground.

5. The dynamic latch according to claim 2, wherein the PMOS transistor has a source terminal, a drain terminal and a gate terminal, the source terminal and the drain terminal of the PMOS transistor are electrically connected to a power supply, and the gate terminal of the PMOS transistor is electrically connected to the node.

6. The dynamic latch according to claim 2, wherein the NMOS transistor has a source terminal, a drain terminal and a gate terminal, the source terminal and the drain terminal of the NMOS transistor are electrically connected to a ground, and the gate terminal of the NMOS transistor is electrically connected to the node.

7. The dynamic latch according to claim 2, wherein the PMOS transistor has a source terminal, a drain terminal and a gate terminal, the source terminal and the gate terminal of the PMOS transistor are electrically connected to a power supply, and the drain terminal of the PMOS transistor is electrically connected to the node.

8. The dynamic latch according to claim 2, wherein the NMOS transistor has a source terminal, a drain terminal and a gate terminal, the source terminal and the gate terminal of the NMOS transistor are electrically connected to a ground, and the drain terminal of the NMOS transistor is electrically connected to the node.

9. The dynamic latch according to claim 1, wherein the clock signal comprises a first clock signal and a second clock signal in a opposite phase.

10. The dynamic latch according to claim 1, wherein the data transmission unit is a transmission gate.

11. The dynamic latch according to claim 10, wherein the transmission gate comprises a plurality of PMOS transistors and a plurality of NMOS transistors connected in parallel, respectively.

12. The dynamic latch according to claim 1, wherein the data output unit is an inverter.

13. A dynamic D flip-flop, comprising:
an input terminal for inputting a first data;
an output terminal for outputting a second data;
a clock signal terminal for supplying a clock signal;
a first latch for latching the first data under control of the clock signal; and
a second latch for receiving and latching a data transmitted by the first latch,
wherein the first latch and the second latch are sequentially connected in series between the input terminal and the output terminal, the first latch comprises a first data transmission unit and a first data output unit, the second latch comprises a second data transmission unit and a second data output unit, a first node is provided between the first data transmission unit and the first data output unit, and a second node is provided between the second data transmission unit and the second data output unit,
the dynamic D flip-flop further comprises:
a data retention unit electrically connected to the first node and/or the second node.

14. The dynamic D flip-flop according to claim 13, wherein the data retention unit has a first terminal electrically connected to the first node, and a second terminal electrically connected to the second node.

15. The dynamic D flip-flop according to claim 14, wherein the data retention unit comprises a PMOS transistor and/or a NMOS transistor.

16. The dynamic D flip-flop according to claim 15, wherein the PMOS transistor comprises a source terminal electrically connected to the first node, a drain terminal electrically connected to the second node, and a gate terminal electrically connected to a power supply, and
the NMOS transistor comprises a source terminal electrically connected to the first node, a drain terminal electrically connected to the second node, and a gate terminal electrically connected to a ground.

17. The dynamic D flip-flop according to claim 15, wherein the PMOS transistor comprises a source terminal and a drain terminal that are electrically connected to the first node, and a gate terminal electrically connected to the second node, and
the NMOS transistor comprises a source terminal and a drain terminal that are electrically connected to the first node, and a gate terminal electrically connected to the second node.

18. The dynamic D flip-flop according to claim 13, wherein the data retention unit is electrically connected to the first node or the second node, and the data retention unit comprises a PMOS transistor and/or a NMOS transistor.

19. The dynamic D flip-flop according to claim 18, wherein the PMOS transistor has a source terminal, a drain terminal and a gate terminal, the source terminal and the drain terminal of the PMOS transistor are electrically connected to the first node, and the gate terminal of the PMOS transistor is electrically connected to a power supply.

20. The dynamic D flip-flop according to claim 18, wherein the NMOS transistor has a source terminal, a drain terminal and a gate terminal, the source terminal and the drain terminal of the NMOS transistor are electrically connected to the first node, and the gate terminal of the NMOS transistor is electrically connected to a ground.

21. The dynamic D flip-flop according to claim 18, wherein the PMOS transistor has a source terminal, a drain terminal and a gate terminal, the source terminal and the drain terminal of the PMOS transistor are electrically connected to a power supply, and the gate terminal of the PMOS transistor is electrically connected to the first node.

22. The dynamic D flip-flop according to claim 18, wherein the NMOS transistor has a source terminal, a drain terminal and a gate terminal, the source terminal and the drain terminal of the NMOS transistor are electrically connected to a ground, and the gate terminal of the NMOS transistor is electrically connected to the first node.

23. The dynamic D flip-flop according to claim 18, wherein the PMOS transistor has a source terminal, a drain terminal and a gate terminal, the source terminal and the gate terminal of the PMOS transistor are electrically connected to a power supply, and the drain terminal of the PMOS transistor is electrically connected to the first node.

24. The dynamic D flip-flop according to claim 18, wherein the NMOS transistor has a source terminal, a drain terminal and a gate terminal, the source terminal and the gate terminal of the NMOS transistor are electrically connected to a ground, and the drain terminal of the NMOS transistor is electrically connected to the first node.

25. The dynamic D flip-flop according to claim 18, wherein the PMOS transistor has a source terminal, a drain terminal and a gate terminal, the source terminal and the drain terminal of the PMOS transistor are electrically connected to the second node, and the gate terminal of the PMOS transistor is electrically connected to a power supply.

26. The dynamic D flip-flop according to claim 18, wherein the NMOS transistor has a source terminal, a drain terminal and a gate terminal, the source terminal and the drain terminal of the NMOS transistor are electrically connected to the second node, and the gate terminal of the NMOS transistor is electrically connected to a ground.

27. The dynamic D flip-flop according to claim 18, wherein the PMOS transistor has a source terminal, a drain terminal and a gate terminal, the source terminal and the drain terminal of the PMOS transistor are electrically connected to a power supply, and the gate terminal of the PMOS transistor is electrically connected to the second node.

28. The dynamic D flip-flop according to claim 18, wherein the NMOS transistor has a source terminal, a drain terminal and a gate terminal, the source terminal and the drain terminal of the NMOS transistor are electrically connected to a ground, and the gate terminal of the NMOS transistor is electrically connected to the second node.

29. The dynamic D flip-flop according to claim 18, wherein the PMOS transistor has a source terminal, a drain terminal and a gate terminal, the source terminal and the gate terminal of the PMOS transistor are electrically connected to a power supply, and the drain terminal of the PMOS transistor is electrically connected to the second node.

30. The dynamic D flip-flop according to claim 18, wherein the NMOS transistor has a source terminal, a drain terminal and a gate terminal, the source terminal and the gate terminal of the NMOS transistor are electrically connected to a ground, and the drain terminal of the NMOS transistor is electrically connected to the second node.

31. The dynamic D flip-flop according to claim 13, wherein the clock signal comprises a first clock signal and a second clock signal in a opposite phase.

32. The dynamic D flip-flop according to claim 13, wherein the data transmission unit is a transmission gate.

33. The dynamic D flip-flop according to claim 13, wherein the data output unit is an inverter.

34. A data operation unit, comprising a control circuit, an operational circuit, and a plurality of dynamic latches interconnected with each other, wherein the plurality of dynamic latches are connected in series and/or in parallel, and the plurality of dynamic latches are the dynamic latch according to claim 1.

35. A data operation unit, comprising a control circuit, an operational circuit, and a plurality of dynamic D flip-flops interconnected with each other, wherein the plurality of dynamic D flip-flops are connected in series and/or in parallel, and the plurality of dynamic D flip-flops are the dynamic D flip-flop according to claim 13.

36. A chip, comprising at least one data operation unit, wherein at least one data operation unit comprises a control circuit, an operational circuit, and a plurality of dynamic latches interconnected with each other, wherein the plurality of dynamic latches are connected in series and/or in parallel, and the plurality of dynamic latches are the dynamic latch according to claim 1.

37. A chip, comprising at least one data operation unit, wherein the at least one data operation unit comprises a control circuit, an operational circuit, and a plurality of dynamic D flip-flops interconnected with each other, wherein the plurality of dynamic D flip-flops are connected in series and/or in parallel, and the plurality of dynamic D flip-flops are the dynamic D flip-flop according to claim 13.

38. A hash board for a computing device, comprising a chip, wherein the chip comprises at least one data operation unit, wherein at least one data operation unit comprises a control circuit, an operational circuit, and a plurality of dynamic latches interconnected with each other, wherein the plurality of dynamic latches are connected in series and/or in parallel, and the plurality of dynamic latches are the dynamic latch according to claim 1.

39. A hash board for a computing device, comprising a chip, wherein the chip comprises at least one data operation unit, wherein the at least one data operation unit comprises a control circuit, an operational circuit, and a plurality of dynamic D flip-flops interconnected with each other, wherein the plurality of dynamic D flip-flops are connected in series and/or in parallel, and the plurality of dynamic D flip-flops are the dynamic D flip-flop according to claim 13.

40. A computing device, comprising a power supply board, a control board, a connection board, a radiator and a plurality of hash boards, the control board is connected to the hash boards through the connection board, the radiator is disposed around the hash boards, the power supply board is configured to supply a power supply to the connection board, the control board, the radiator and the hash boards, wherein the hash boards each comprises a chip, wherein the chip comprises at least one data operation unit, wherein at least one data operation unit comprises a control circuit, an operational circuit, and a plurality of dynamic latches interconnected with each other, wherein the plurality of dynamic latches are connected in series and/or in parallel, and the plurality of dynamic latches are the dynamic latch according to claim 1.

41. A computing device, comprising a power supply board, a control board, a connection board, a radiator and a plurality of hash boards, the control board is connected to the hash boards through the connection board, the radiator is disposed around the hash boards, the power supply board is configured to supply a power supply to the connection board, the control board, the radiator and the hash boards, wherein the hash boards each comprises a chip, wherein the chip comprises at least one data operation unit, wherein the at least one data operation unit comprises a control circuit, an operational circuit, and a plurality of dynamic D flip-flops interconnected with each other, wherein the plurality of dynamic D flip-flops are connected in series and/or in parallel, and the plurality of dynamic D flip-flops are the dynamic D flip-flop according to claim 13.
